(19) United States
(12) Patent Application Publication
(10) Pub. No.: US 2024/0079303 A1
(43) Pub. Date: Mar. 7, 2024

(54) SEMICONDUCTOR PACKAGE SUBSTRATE WITH HYBRID CORE STRUCTURE AND METHODS FOR MAKING THE SAME

(71) Applicant: Taiwan Semiconductor Manufacturing Company Limited, Hsinchu (TW)

(72) Inventor: Wei-Hung Lin, Xinfeng Township (TW)

(21) Appl. No.: 18/303,663

(22) Filed: Apr. 20, 2023

Related U.S. Application Data
(60) Provisional application No. 63/403,879, filed on Sep. 6, 2022.

(51) Int. Cl. H01L 23/498; H01L 23/00; H01L 23/28; H01L 23/367; H01L 23/538; H01L 25/065; H05K 3/46

(52) U.S. Cl. CPC H01L 23/49827; H01L 23/28; H01L 23/3675; H01L 23/49838; H01L 23/538; H01L 24/05; H01L 25/0657; H05K 3/4626; H01L 2224/05008; H01L 2924/181; H01L 2924/351; H05K 2201/068

(57) ABSTRACT

A package substrate and a method of fabrication thereof including a hybrid substrate core having different material properties in different portions of the core. A first portion of the hybrid substrate core may have a lower coefficient of thermal expansion (CTE) compared to a second portion of the hybrid substrate core. The CTE of the first portion of the hybrid substrate core may be close to the CTE of semiconductor integrated circuit dies mounted to a first side of the package substrate in an assembled semiconductor package. The CTE of the second portion of the hybrid substrate core may be close to the CTE of a supporting substrate, such as a printed circuit board, to which the semiconductor package is mounted. The package substrate may help to balance stress, such as thermally-induced stress, in the semiconductor package, thereby improving package reliability.

### RELATED APPLICATIONS

This application claims priority from U.S. Provisional Application Ser. No. 63/403,879 entitled “Semiconductor Package Substrate with Hybrid Core Structure And Methods For Making The Same,” filed on Sep. 6, 2022, the entire contents of which are incorporated herein by reference for all purposes.

### BACKGROUND

Semiconductor devices are used in a variety of electronic applications. Some examples may include personal computers, cell phones, digital cameras, and other electronic equipment. Semiconductor devices are typically fabricated by sequentially depositing insulating or dielectric layers, conductive layers, and semiconductive layers of material over a semiconductor substrate, and patterning the various material layers using lithography to form circuit components and elements thereon. Dozens or hundreds of integrated circuits are typically manufactured on a single semiconductor wafer, and individual dies on the wafer are singulated by sawing between the integrated circuits along a scribe line. The individual dies are typically packaged separately, for example, in multi-chip modules, or in other types of packaging. As semiconductor packages have become larger and more complex, ensuring mechanical integrity of the package has become more difficult.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a vertical cross-section view of an exemplary intermediate structure during a process of forming a package substrate including a hybrid substrate core having a first portion adjacent to a first side of the hybrid substrate core, a second portion adjacent to a second side of the hybrid substrate core, and a third portion located between the first portion and the second portion of the hybrid substrate core according to various embodiments of the present disclosure.

FIG. 2 is a vertical cross-section view of an exemplary intermediate structure during a process of fabricating a package substrate illustrating a plurality of conductive vias extending through a hybrid substrate core according to various embodiments of the present disclosure.

FIG. 3 is a vertical cross-section view of an exemplary intermediate structure during a process of fabricating a package substrate illustrating a redistribution layer formed over the first surface of the hybrid substrate core according to various embodiments of the present disclosure.

FIG. 4 is a vertical cross-section view of an exemplary intermediate structure during a process of fabricating a package substrate illustrating a redistribution layer formed over the second surface of the hybrid substrate core according to various embodiments of the present disclosure.

FIG. 5 is a vertical cross-section view of a package substrate including outer coating layers located above and below the respective redistribution layers according to various embodiments of the present disclosure.

FIG. 6 is a vertical cross-section view of a semiconductor package including a package structure mounted over the first side of a package substrate according to various embodiments of the present disclosure.

FIG. 7 is a vertical cross-section view of a semiconductor package including a second underfill material portion located between the first side of the package substrate and the lower surface of the interposer according to various embodiments of the present disclosure.

FIG. 8 is a vertical cross-section view of a semiconductor package mounted to a supporting substrate according to various embodiments of the present disclosure.

FIG. 9 is a vertical cross-section view of a semiconductor package mounted to a supporting substrate according to an alternative embodiment of the present disclosure.

FIG. 10 is a flowchart illustrating a method of fabricating a package substrate according to various embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Various embodiments disclosed herein may be directed to semiconductor devices, and in particular to a substrate for a semiconductor package, and methods of fabrication thereof, that includes a hybrid substrate core having different material properties in different portions of the substrate core.

Typically, in a semiconductor package a number of semiconductor integrated circuit (IC) dies (i.e., “chips”) may be mounted onto a common substrate, which may also be referred to as a “package substrate.” In some packages, such as in a fan out wafer level package (FOWLP) and/or fan-out panel level package (FOPLP), a plurality of semiconductor IC dies may be mounted to an interposer, such as an organic interposer or a semiconductor (e.g., silicon) interposer, that may include interconnect structures extending therethrough. The resulting package structure, including the interposer and the semiconductor IC dies mounted thereon, may then be mounted onto a surface of a package substrate using solder connections to form a semiconductor package. The semiconductor package, including the package substrate and the package structure mounted thereon, may then be mounted to a supporting substrate, such as a printed circuit board (PCB).

As semiconductor packages have become larger and more complex by integrating greater numbers of semiconductor IC dies, ensuring the mechanical stability of the semiconductor package has become more important. In many semiconductor packages, stresses including thermally-induced stresses may result in an increasing failure rate and decreased reliability of the semiconductor package.

Various embodiments disclosed herein include package substrates and methods of fabricating package substrates that include a hybrid substrate core. The hybrid substrate core may include multiple portions (e.g., sub-layers) of the substrate core having different material properties. In various embodiments, the hybrid substrate core may include a first portion that is closest to the semiconductor package structure and a second portion that is closest to the supporting substrate (e.g., PCB) in the assembled semiconductor package. The first portion of the hybrid substrate core may also be referred to as a “chip-side” portion of the hybrid substrate core, and the second portion of the hybrid substrate core may also be referred to as a “board-side” portion of the hybrid substrate core. The first portion of the hybrid substrate core may have a lower coefficient of thermal expansion (CTE) than the CTE of the second portion of the hybrid substrate core. In various embodiments, the CTE of the first portion of the hybrid substrate core may be relatively closer (e.g., within 0-5 ppm/° C.) to the CTE of the semiconductor IC dies of the package structure, and the CTE of the second portion of the hybrid substrate may be relatively closer (e.g., within 0-10 ppm/° C.) of the CTE of the support substrate (e.g., PCB). In some embodiments, the first portion of the hybrid substrate core may have a higher Young's modulus than the second portion of the hybrid substrate core. In some embodiments, the hybrid substrate core may also include a third portion (which may also be referred to as a “buffer portion”) located between the first portion and the second portion of the hybrid substrate core. The third portion may have a CTE that is greater than the CTE of the first portion of the hybrid substrate core and less than the CTE of the second portion of the hybrid substrate core.

A package substrate according to various embodiments may include a hybrid substrate core as described above, a plurality of conductive interconnect structures (e.g., metal vias) extending through the hybrid substrate core between a first surface and a second surface of the hybrid substrate core, first and second redistribution layers including conductive interconnect structures embedded in a dielectric material matrix located over the respective first and second surfaces of the hybrid substrate core, and optional first and second outer coating layers located over the respective first and second redistribution layers.

A package substrate including a hybrid substrate core having different material properties in different portions of the core may help to balance stress between the package substrate and a package structure including one or more semiconductor IC dies coupled to a first side of the package substrate, and a supporting substrate coupled to the second side of the package substrate. This may result in improved reliability and decreased failure rates of semiconductor packages.

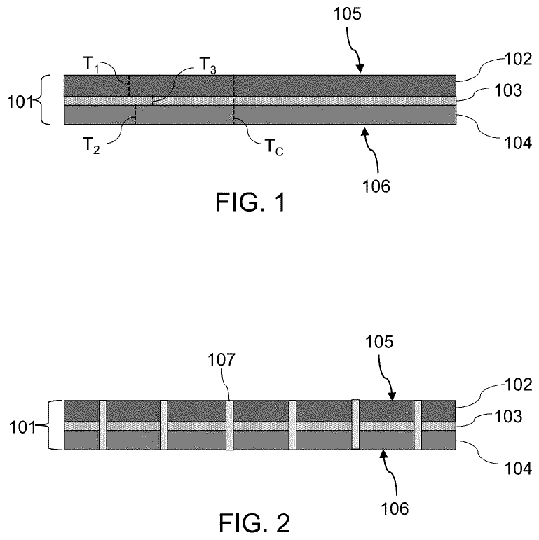

FIGS. 1-5 are sequential vertical cross-section views of an exemplary intermediate structures that are formed during a process of fabricating a package substrate according to various embodiments of the present disclosure. Referring to FIG. 1, a hybrid substrate core 101 is illustrated including a first portion 102 adjacent to a first side 105 of the hybrid substrate core 101 and a second portion 104 adjacent to a second side 106 of the hybrid substrate core 101. An optional third portion 103 of the hybrid substrate core 101 may be located between the first portion 102 and the second portion 103. The first portion 102, the second portion 104 and the optional third portion 103 may each include thin sheets of structural material that may be bonded together using a suitable adhesive, such as an adhesive film, to form the hybrid substrate core 101. In some embodiments, the first portion 102, the second portion 104 and the optional third portion 103 may be bonded together using a partially-cured epoxy resin, such as a B-stage material. The B-stage material may include one or more layers (i.e., plies) of a prepreg material that includes a glass fiber or cloth material impregnated with a resin that may be partially-dried via heat and/or UV radiation. In various embodiments, the first portion 102, the second portion 104 and the optional third portion 103 may be stacked with one or more layers of B-stage prepreg material located between the first portion 102, the second portion 104 and the third portion 103, respectively, and subjected to a press lamination process and a final cure to form the hybrid substrate core 101. In some embodiments, a layer of copper foil may be provided over the upper and lower surfaces of the stack during the press lamination process to provide a hybrid substrate core 101 including layers of copper material over the first side 105 and the second side 106 of the hybrid substrate core 101. Thus, in the embodiment shown in FIG. 1, the first portion 102, the second portion 104 and the third portion 103 may form a first sublayer 102, a second sublayer 104 and a third sublayer 103, respectively, of a bonded laminate-structure hybrid substrate core 101. It may be understood that other configurations for the hybrid substrate core 101 are within the contemplated scope of disclosure, including embodiments in which the hybrid substrate core 101 may be formed as a unitary structure including a first portion 102 adjacent to the first surface 105, a second portion 104 adjacent to the second surface 106, and an optional third portion 103 between the first portion 102 and the second portion 104.

In some embodiments, the first portion 102, the second portion 104 and the optional third portion 103 of the hybrid substrate core 101 may each be composed of a sheet of laminate reinforced resin. The laminate reinforced resin sheet may include a reinforcement material (e.g., glass fiber or cloth) that is impregnated with a resin system, such as an epoxy-based resin system, and is cured under heat and pressure to form a sheet of laminate reinforced resin. Other suitable materials and constructions for the first portion 102, the second portion 103 and the optional third portion 103 of the hybrid substrate core 101 are within the contemplated scope of disclosure. In various embodiments, the first portion 102 of the hybrid substrate core 101 may have a thickness dimension, T₁, that is between about 0.2 mm and about 0.6 mm, although thicker or thinner dimensions may be used. In various embodiments, the second portion 104 of the hybrid substrate core 101 may have a thickness dimension, T₂, that is between about 0.2 mm and about 0.6 mm, although thicker or thinner dimensions may be used. The optional third portion 103 of the hybrid substrate core 101 may have a thickness dimension, T₃, that is between about 0.01 mm and about 0.2 mm, although thicker or thinner dimensions may be used. The hybrid substrate core 101 may have a total thickness, T_{c}, that is between about 0.4 mm and about 1.0 mm, although thicker or thinner dimensions may be used.

In various embodiments, the first portion 102, the second portion 104 and, in embodiments in which the third portion 103 of the hybrid substrate core 101 is present, may each have different material properties, such as a different coefficient of thermal expansion (CTE) and/or a different modulus of elasticity (i.e., Young's modulus). In various embodiments, the first portion 102 of the hybrid substrate core 101 may have a CTE that is less than the CTE of the second portion 104 of the hybrid substrate core 101. In some embodiments, the first portion 102 of the hybrid substrate core 101 may have a CTE of less than 10 ppm/° C., such as between about 0.1 ppm/° C. and about 6 ppm/° C., at temperatures below its glass transition temperature (T_{g}). In some embodiments, the second portion 104 of the hybrid substrate core 101 may have a CTE of 10 ppm/° C. or more, such a CTE between 10 ppm/° C. and about 30 ppm/° C., at temperatures below its glass transition temperature (T_{g}). In various embodiments, the CTE of the third portion 103 of the hybrid substrate core 101, if present, may have a CTE that is between the CTE of the first portion 102 and the second portion 102 of the hybrid substrate core 101.

In various embodiments, the first portion 102 of the hybrid substrate core 101 may have a Young's modulus that is greater than the Young's modulus of the second portion 104 of the hybrid substrate core 101. In some embodiments, the first portion 102 of the hybrid substrate core 101 may have a Young's modulus between about 30 GPa and about 50 GPa at room temperature (e.g., ˜20° C.). The second portion 104 of the hybrid substrate core 101 may have a Young's modulus between about 10 GPa and about 40 GPa at room temperature. In embodiments in which the third portion 103 of the hybrid substrate core 101 is present, the third portion 103 may have a Young's modulus within a range between about 1 GPa and about 50 GPa at room temperature.

The differences in material properties between the first portion 102 and the second portion 104 of the hybrid substrate core 101 may help to balance the effects of stress, such as thermally-induced stress, when the package substrate is assembled in a semiconductor package. The first portion 102 of the hybrid substrate core 101 may be in closest proximity to a semiconductor package structure including one or more semiconductor IC dies in the assembled semiconductor package. Thus, the lower CTE of the first portion 102 of the hybrid substrate core 101 may more closely match the relatively lower CTE of components of the semiconductor package structure, including the one or more semiconductor IC dies. The relatively higher Young's modulus of the first portion 102 of the hybrid substrate core 101 may provide a higher resistance to mechanical strain, which may help to maintain the structural integrity of the coupling between the package substrate and the semiconductor package structure.

In addition, the relatively higher CTE of the second portion 104 of the hybrid substrate core 101 may more closely match the CTE of the supporting substrate of the assembled semiconductor package, such as a printed circuit board (PCB), which generally has a higher CTE than components of the semiconductor package structure, including the semiconductor IC die(s). The relatively lower Young's modulus of the second portion 104 of the hybrid substrate core 101 may provide a “cushion” effect that may help to mitigate stresses resulting from the CTE mismatch between the semiconductor package structure coupled to a first side of the package substrate and the supporting substrate (e.g., PCB) coupled to the second side of the package substrate. In embodiments in which the optional third portion 103 of the hybrid substrate core 101 is present, the third portion 103 may function as a “buffer” between the first portion 102 and the second portion 104 of the hybrid substrate core 101.

The different material properties of the first portion 102, the second portion 104 and the optional third portion 103 of the hybrid substrate core 101 may be obtained by varying different process parameters and/or materials used to form the first portion 102, the second portion 104 and the optional third portion 103 of the hybrid substrate core 101. In the case of laminate reinforced resin materials, for example, such variations may include, without limitation, variations in the composition of the reinforcement material, including the type of reinforcement material used (e.g., E-glass, S-Glass, LowDk-glass, silica, quartz, aramid, etc.), variations in the physical characteristics of the reinforcement material (e.g., use of woven or non-woven fiber reinforcement material, weave pattern of woven fiber reinforcement material, diameter, length and/or alignment of fiber reinforcement material, etc.), variations in the composition of the resin system utilized, variations in the curing process, and variations in the relative concentrations of reinforcement material and resin in the laminate reinforced resin product. A number of commercially available products may be suitable for use in various embodiments of the invention. For example, in recent years a number of substrate core materials characterized by low- or extra-low CTE and high Young's modulus have come onto the market and may be suitable for use as a first portion 102 of a hybrid substrate core 101. Examples of suitable products for the first portion 102 of the hybrid substrate core 101 may include, without limitation, the MCL-E-705G series and the MCL-E-795G series of products from Showa Denko Materials Co., Ltd., Tokyo, JP, the HL832NSA(LCA) product from Mitsubishi Chemical Corp., Tokyo, JP, and the R-1515V product from Panasonic Holdings Corp., Osaka, JP. Other suitable materials for use as the first portion 102 of the hybrid substrate core 101 are within the contemplated scope of disclosure. Examples of suitable materials for use as the second portion 104 of the hybrid substrate core 101 may include, for example, the MCL-HE-679G (Type S) product from Showa Denko Materials Co., Ltd., Tokyo, JP, and the HL832NX product from Mitsubishi Chemical Corp., Tokyo, JP. Other suitable materials for use as the second portion 104 of the hybrid substrate core 101 are within the contemplated scope of disclosure. The material of the optional third portion 103 of the hybrid substrate core 101 may be selected such that the CTE of the optional third portion 103 is between the CTE of the first portion 102 and the second portion 104 of the hybrid substrate core 101.

FIG. 2 is a vertical cross-section view of an exemplary intermediate structure during a process of fabricating a package substrate illustrating a plurality of conductive vias 107 extending through a hybrid substrate core 101 according to various embodiments of the present disclosure. Referring to FIG. 2, a plurality of through-holes may be formed through the hybrid substrate core 101 extending between the first surface 105 and the second surface 106 of the hybrid substrate core 101. In the embodiment shown in FIG. 2, the plurality of through-holes are formed through the first portion 102, the second portion 104 and the third portion 103 of the hybrid substrate core 101 after the first portion 102, the second portion 104 and the third portion 103 are bonded together. In other embodiments, through-holes may be formed through one or more of the first portion 102, the second portion 104 and the third portion 103 prior to being bonded together to form the hybrid substrate core 101. The through-holes may be formed using any suitable process, such as mechanical drilling, laser drilling, or an etching process through a photolithographic ally-patterned mask. Other suitable processes for forming the through-holes are within the contemplated scope of disclosure.

Referring again to FIG. 2, a plurality of conductive vias 107 may be formed within each of the through-holes such that the conductive vias 107 extend between the first surface 105 and the second surface 106 of the hybrid substrate core 101. The conductive vias 107 may be formed of a suitable conductive material, such as Cu, Ni, W, Al, Co, Mo, Ru, and the like, including combinations and alloys thereof. Other suitable materials for the conductive vias 107 are within the contemplated scope of disclosure. The plurality of conductive vias 107 may be formed using a suitable deposition process, such as an electrochemical deposition process (e.g., electroplating). Other suitable deposition processes are within the contemplated scope of disclosure. In the embodiment shown in FIG. 2, the plurality of conductive vias 107 may be formed after the first portion 102, the second portion 104 and the third portion 103 are bonded together to form the hybrid substrate core 101. Alternatively, conductive vias may be formed through one or more of the first portion 102, the second portion 104 and the third portion 103 of the hybrid substrate core 101 prior to being bonded together, such that when the first portion 102, the second portion 104 and the third portion 103 are bonded together, a plurality of conductive vias 107 extend continuously through the first portion 102, the second portion 104 and the third portion 103 between the first surface 105 and the second surface 106 of the hybrid substrate core 101.

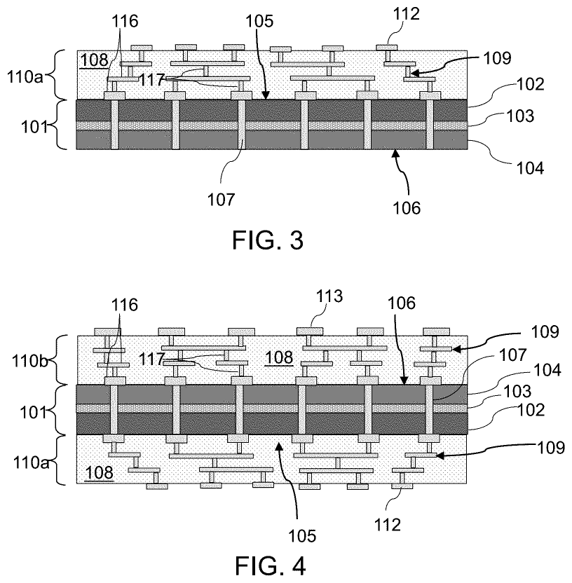

FIG. 3 is a vertical cross-section view of an exemplary intermediate structure during a process of fabricating a package substrate illustrating a first redistribution layer 110a formed over the first surface 105 of the hybrid substrate core 101 according to various embodiments of the present disclosure. The first redistribution layer 110a may include a plurality of conductive interconnect structures 109 (e.g., metal lines 116 and vias 117) embedded in a dielectric material matrix 108. The conductive interconnect structures 109 may contact the plurality of conductive vias 107 extending through the hybrid substrate core 101.

In some embodiments, the first redistribution layer 110a may be formed by providing a first layer of a conductive material (e.g., a copper clad laminate) over the first surface 105 of the hybrid substrate core 101 using a suitable deposition process, such as an electroplating process. In some embodiments, the first layer of conductive material over the first surface 105 of the hybrid substrate core 101 may be formed, in whole or in part, via the above-described press lamination process used to form the hybrid substrate core 101. The first layer of conductive material may be patterned via an etching process performed through a photolithographically-patterned mask to form a first plurality of metal lines 116 (e.g., copper traces) over the first surface 105 of the hybrid substrate core 101. A first layer of dielectric material 108 may then be formed over the first plurality of metal lines 116. The first layer of dielectric material 108 may include a polymer-based dielectric material, such as an Ajinomoto Buildup Film (ABF)® product from Ajinomoto Co., Inc., Tokyo, JP. Other suitable dielectric materials are within the contemplated scope of disclosure. In some embodiments, the first layer of dielectric material 108 may be applied as a film over the first surface 105 of the hybrid substrate core 101. The film may be vacuum laminated over the first surface 105 of the hybrid substrate core 101 and partially cured (e.g., via a hot-pressing process). A plurality of through-holes may be formed through the first layer of dielectric material 108 using a suitable process, such as by mechanical drilling, laser drilling, and/or an etching process. A metal line 116 and/or conductive via 107 may be exposed at the bottom of each of the through-holes.

A metallization process may be used to form a first plurality of vias 117 within the through-holes through the first layer of dielectric material 108. The first plurality of vias 117 may be formed using a suitable deposition process, such as electroplating. The deposition process may also form a second layer of conductive material over the first layer of dielectric material 108. Alternatively, a separate deposition process may be used to form a second layer of conductive material over the first layer of dielectric material 108. The second layer of conductive material may be patterned via an etching process performed through a photolithographically-patterned mask to form a second plurality of metal lines 116 (e.g., copper traces) over the surface of the first layer of dielectric material 108. A second layer of dielectric material 108 may be formed over the second plurality of metal lines 116 as described above, and a plurality of through-holes may be formed through the second layer of dielectric material 108. An additional metallization process may be used to form a second plurality of vias 117 within the through-holes formed through the second layer of dielectric material 108. These processes may optionally be repeated a number of times to form the first redistribution layer 110a including a plurality of conductive interconnect structures 109 (e.g., metal lines 116 and vias 117) embedded in a dielectric material matrix 108. The layers of the dielectric material 108 may optionally be subjected to curing process at an elevated temperature (e.g., 170-200° C.) to form a solid dielectric material matrix 108 surrounding the conductive interconnect structures 109. A first plurality of bonding pads 112 may be formed over the uppermost layer of the dielectric material 108.

FIG. 4 is a vertical cross-section view of an exemplary intermediate structure during a process of fabricating a package substrate illustrating a second redistribution layer 110b formed over the second surface 106 of the hybrid substrate core 101 according to various embodiments of the present disclosure. Referring to FIG. 4, the second redistribution layer 110b over the second surface 106 of the hybrid substrate core 101 may include a plurality of conductive interconnect structures 109 (e.g., metal lines 116 and vias 117) embedded in a dielectric material matrix 108. The second redistribution layer 110b over the second surface 106 of the hybrid substrate core 101 may include a similar or identical construction and may be formed using similar or identical processes to the first redistribution layer 110a formed over the first surface 105 of the hybrid substrate core 101 as described above with referent to FIG. 3. Thus, repeated discussion of like features is omitted for brevity. Further, although FIG. 3 and FIG. 4 illustrate an embodiment in which the first redistribution layer 110a formed over the first surface 105 of the hybrid substrate core 101 prior to the formation of the second redistribution layer 110b over the second surface 106 of the hybrid substrate core 101, it will be understood that the second redistribution layer 110b over the second surface 106 of the hybrid substrate core 101 may be formed prior to the formation of the first redistribution layer 110a over the first surface 105 of the hybrid substrate core 101, or the first redistribution layer 110a and second redistribution layer 110a (collectively, redistribution layers 110) may be formed at the same time over the first surface 105 and the second surface 106 of the hybrid substrate core 101.

Referring again to FIG. 4, a second plurality of bonding pads 113 may be formed over the second redistribution layer 110b located over the second surface 106 of the hybrid substrate core 101. In various embodiments, the first plurality of bonding pads 112 may be configured to electrically connect the package substrate to a semiconductor package structure including at least one semiconductor IC die, and the second plurality of bonding pads 113 may be configured to electrically connect the package substrate to a supporting substrate, such as a PCB.

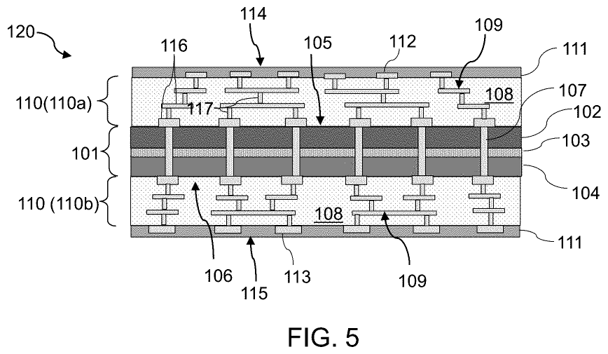

FIG. 5 is a vertical cross-section view of a package substrate 120 including outer coating layers 111 located above and below the respective redistribution layers 110 according to various embodiments of the present disclosure. Referring to FIG. 5, the outer coating layers 111 of the package substrate 120 may include a layer of dielectric material formed over the respective redistribution layers 110 and defining respective first outer surface 114 and second outer surface 115 of the package substrate 120. Each of the outer coating layers 111 may provide a protective coating for the package substrate 120 and the underlying bonding pads 112, 113 and conductive interconnect structures 109 within the package substrate 120. The outer coating layers 111 may also inhibit solder material from adhering to the respective first and second surfaces 114 and 115 of the package substrate 120 during a subsequent solder reflow process.

In various embodiments, the outer coating layers 111 may include a solder resist material. The outer coating layers 111 formed of solder resist material may also be referred to as “solder masks.” The solder resist material of the outer coating layers 111 may include a suitable resin material that is resistant to humidity and high-temperature, and to which a solder material will not strongly adhere. The solder resist material of the outer coating layers 111 may be formed using a suitable deposition process, such as via screen printing, spraying, and/or vacuum lamination. Other suitable deposition processes are within the contemplated scope of disclosure.

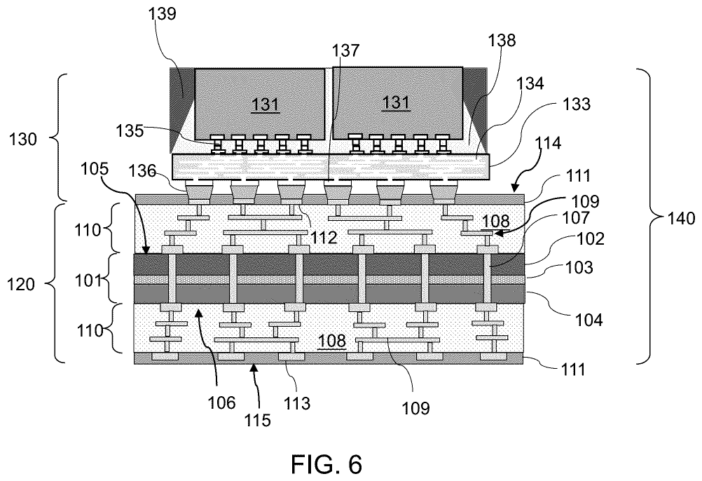

FIG. 6 is a vertical cross-section view of a semiconductor package 140 including a package structure 130 mounted over the first side 114 of the package substrate 120 according to various embodiments of the present disclosure. Referring to FIG. 6, the package structure 130 may include one or more semiconductor IC dies 131. In the embodiment shown in FIG. 6, the package structure 130 includes two semiconductor IC dies 131, although it will be understood that in other embodiments a package structure 130 may include more than two semiconductor IC dies 131 or may include a single semiconductor IC die 131. The one or more semiconductor IC dies 131 of the package structure 130 may include at least one system-on-chip (SoC) die. An SoC die may include, for example, an application processor die, a central processing unit die, and/or a graphic processing unit die. In some embodiments, the one or more semiconductor IC dies 131 may include at least one memory die. The at least one memory die may include a high bandwidth memory (HBM) die. In some embodiments, a HBM die may include a vertical stack of interconnected memory dies. Alternatively, or in addition, the at least one memory die may include a dynamic random access memory (DRAM) die. In some embodiments, the package structure 130 may include a plurality of semiconductor IC dies 131 that are homogeneous, meaning that all of the semiconductor IC dies 131 may be of the same type (e.g., all SoC dies, all HBM dies, all DRAM dies, etc.). Alternatively, the package structure 130 may include a plurality of semiconductor IC dies 131 that are heterogeneous, meaning that the plurality of semiconductor IC dies 131 may include different types of semiconductor IC dies 131 (e.g., at least one SoC die and at least one memory die).

In various embodiments, the one or more semiconductor IC dies 131 of the package structure 130 may be mounted to an interposer 133, such as an organic interposer or a semiconductor (e.g., silicon) interposer. The interposer 133 may be mounted to the first surface 114 of the package substrate 120 to form a semiconductor package 140. The interposer 133 may include a plurality of interconnect structures 134 (e.g., metal lines and vias) within an insulating matrix. The one or more semiconductor IC dies 131 may be mounted to the interposer 133 via a plurality of bonding structures 135, which may include microbump (e.g., C2) bonding structures. A first underfill material portion 138 may be disposed between the one or more semiconductor IC dies 131 and the interposer 133, and may surround the bonding structures 135. A molding portion 139, which may include, for example, an epoxy mold compound (EMC), may laterally surround the one or more semiconductor IC dies 131.

Referring again to FIG. 6, an etching process may be used to selectively remove portions of the outer coating layer 111 (e.g., solder mask) from the first side 114 of the package substrate 120 and expose the underlying first bonding pads 112 of the package substrate 120. The pattern of first bonding pads 112 exposed in the first side 114 of the package substrate 120 may correspond to a pattern of bonding pads 137 located on a lower surface of the interposer 133. The package structure 130 may be aligned over the first side 114 of the package substrate 120 such that an array of solder material portions 136 are located between the first bonding pads 112 of the package substrate 120 and the corresponding bonding pads 137 on the lower surface of the interposer 133. A reflow process may be performed to reflow the solder material portions 136, thereby inducing bonding between the interposer 133 of the package structure 130 and the package substrate 120. Each of the solder material portions 136 may be bonded to a respective one of the first bonding pads 112 of the package substrate 120 and a respective one of the bonding pads 137 on the lower surface of the interposer 133. In some embodiments, the solder material portions 136 may include C4 solder balls, and the package structure 130 may be bonded to the substrate package 120 through an array of C4 solder balls.

In alternative embodiments, the interposer 133 may be omitted, and the one or more semiconductor IC dies 131 may be directly mounted to the first side 114 of the package substrate 120, such as via a plurality of microbump (e.g., C2) bonding structures.

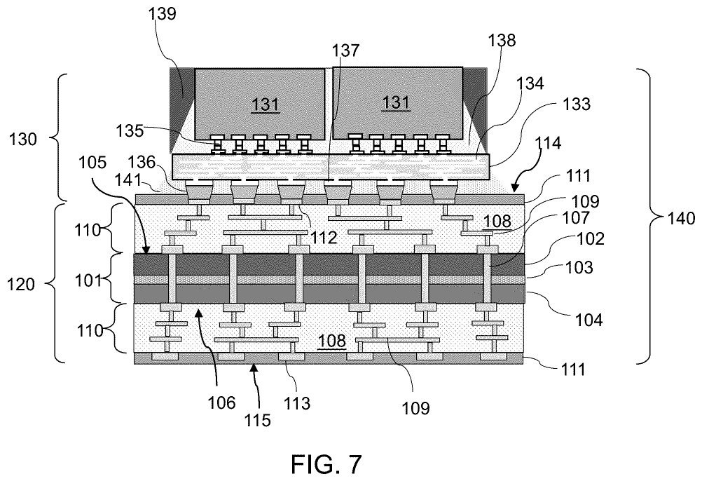

FIG. 7 is a vertical cross-section view of a semiconductor package 140 including a second underfill material portion 141 located between the first side 114 of the package substrate 120 and the lower surface of the interposer 133 according to various embodiments of the present disclosure. Referring to FIG. 7, the second underfill material portion 141 may be applied into the space between the first side 114 of the package substrate 120 and the lower surface of the interposer 133. The second underfill material portion 141 may laterally surround and contact each of the solder material portions 136 that bond the interposer 133 to the package substrate 120.

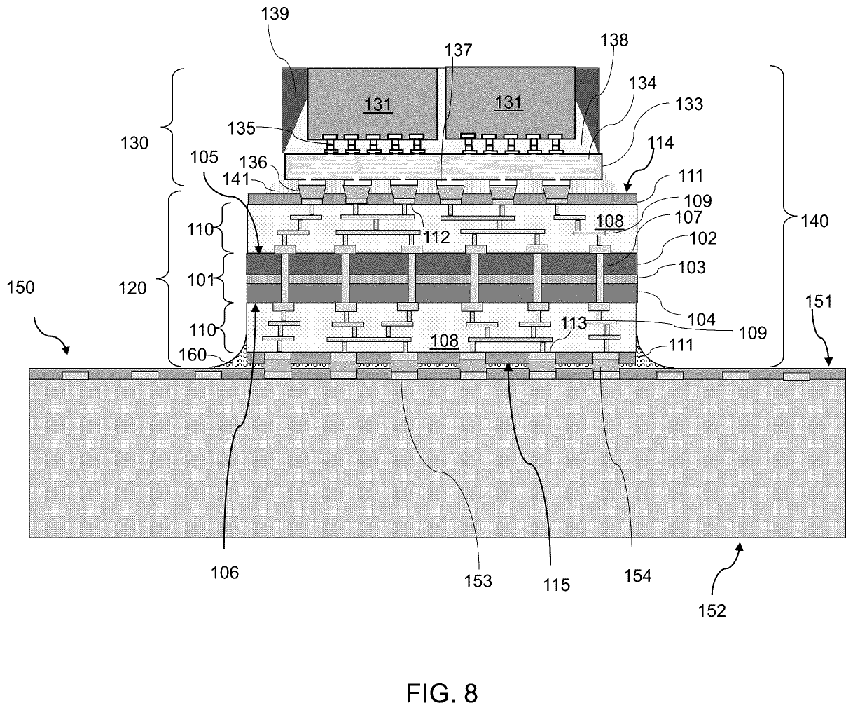

FIG. 8 is a vertical cross-section view of a semiconductor package 140 mounted to a supporting substrate 150 according to various embodiments of the present disclosure. Referring to FIG. 8, the supporting substrate 150 may be a PCB including an array of bonding pads 153 exposed on an upper surface 151 of the supporting substrate 150. An etching process may be used to selectively remove portions of the outer coating layer 111 (e.g., solder mask) from the second side 115 of the package substrate 120 and expose the underlying second bonding pads 113 of the package substrate 120. The pattern of second bonding pads 112 of the package substrate 120 may correspond to the pattern of bonding pads 153 on the upper surface 151 of the supporting substrate 150. The semiconductor package 140 may be aligned over the upper surface 151 of the support substrate 150 such that an array of solder material portions 154 are located between the second bonding pads 113 of the package substrate 120 and the corresponding bonding pads 153 on the upper surface 151 of the supporting substrate 150. A reflow process may be performed to reflow the solder material portions 154, thereby inducing bonding between the package substrate 120 of the semiconductor package 140 and the supporting substrate 150. Each of the solder material portions 154 may be bonded to a respective one of the second bonding pads 113 of the package substrate 120 and a respective one of the bonding pads 153 on the upper surface 151 of the supporting substrate 150. In some embodiments, a third underfill material portion 160 may be applied into the space between the second side 115 of the package substrate 120 and the upper surface 151 of the supporting substrate 150. The third underfill material portion 160 may laterally surround and contact each of the solder material portions 154 that bond the package substrate 120 to the supporting substrate 150.

Referring again to FIG. 8, the semiconductor package 140 according to various embodiments includes a package structure 130 including one or more semiconductor IC dies 131 mounted to a first side 114 of a package substrate 120. A second side 115 of the package substrate 120 is mounted to an upper surface 151 of a supporting substrate 150, such as a PCB. The package substrate 120 includes a hybrid substrate core 101 having a first portion 102 that is most proximate to the first side 114 of the package substrate 120, a second portion 104 that is most proximate to the second side 115 of the package substrate 120, and an optional third portion 103 located between the first portion 102 and the second portion 104. In various embodiments, the first portion 102 of the hybrid substrate core 101 may have a CTE that is within 5 ppm/° C., such as within 3 ppm/° C., including within 2 ppm/° C., of the CTE of a semiconductor IC die 131 of the semiconductor package 140. In some embodiments, the first portion 102 of the hybrid substrate core 101 may have a CTE that is within 1 ppm/° C., including within 0.5 ppm/° C., such as within 0.1 ppm/° C. of the CTE of a semiconductor IC die 131 of the semiconductor package 140. In some embodiments, the semiconductor package 140 may include multiple semiconductor IC dies 131, and the first portion 102 of the hybrid substrate core 101 may have a CTE that is within 5 ppm/° C., such as within 3 ppm/° C., 2 ppm/° C., 1 ppm/° C., 0.5 ppm/° C., or 0.1 ppm/° C. of each semiconductor IC die 131 of the semiconductor package 140. In various embodiments, the second portion 104 of the hybrid substrate core 101 may have a CTE that is within 10 ppm/° C., including within 5 ppm/° C., such as within 3 ppm/° C., of the CTE of the supporting substrate (e.g., PCB) to which the package substrate 120 is mounted. The third portion 103 of the hybrid substrate core 101 may have a CTE that is between the respective CTEs of the first portion 102 and the second portion 104 of they hybrid substrate core 101.

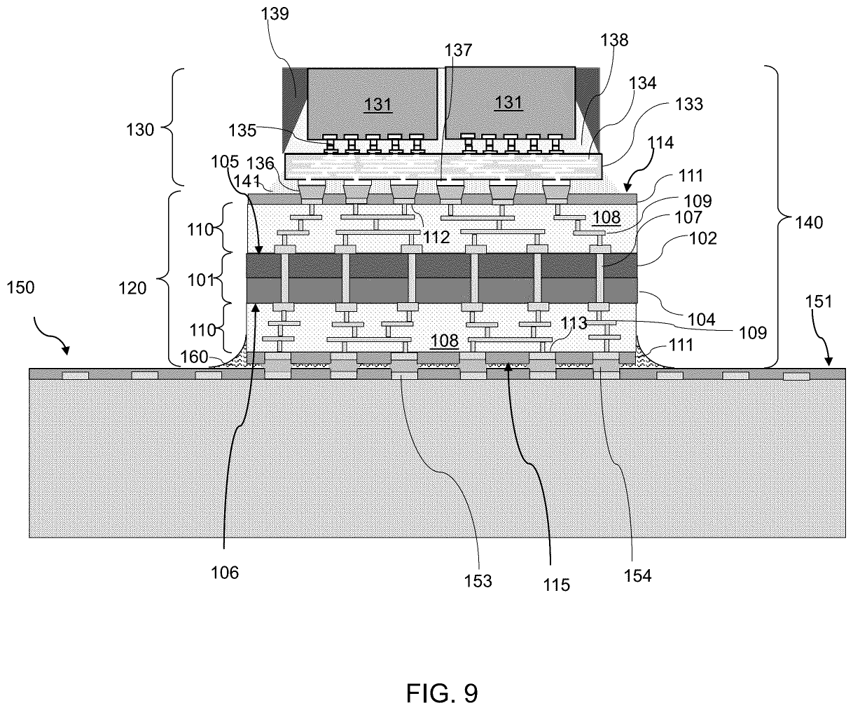

FIG. 9 is a vertical cross-section view of a semiconductor package 140 mounted to a supporting substrate 150 according to an alternative embodiment of the present disclosure. The semiconductor package 140 shown in FIG. 8 may be substantially similar to the semiconductor package 140 described above with reference to FIG. 8. Thus, repeated discussion of like features is omitted for brevity. The semiconductor package 140 shown in FIG. 9 differs from the semiconductor package 140 of FIG. 8 in that the optional third portion 103 of the hybrid substrate core 101 is omitted from the package substrate 120 in the alternative embodiment shown in FIG. 9. Thus, in the embodiment shown in FIG. 9, the hybrid substrate core 101 of the package substrate 120 includes a first portion 102 that is most proximate to the first side 114 of the package substrate 120 and a second portion 104 that is most proximate to the second side 115 of the package substrate 120, where the first portion 102 and the second portion 104 of the hybrid substrate core 101 are adjacent to one another.

As discussed above, a package substrate 120 including a hybrid substrate core 101 may help to balance stress in the assembled semiconductor package 140 such as shown in FIGS. 8 and 9. The first portion 102 of the hybrid substrate core 101 is in closest proximity to a semiconductor package structure 130 including one or more semiconductor IC dies 131, and may have a CTE that is close (e.g., within 5 ppm/° C.) to the CTE of one or more semiconductor IC dies 131. The second portion 104 of the hybrid substrate core 101 is in closest proximity to the supporting substrate 150 (e.g., PCB), and may have a CTE that is close (e.g., within 10 ppm/° C.) to the CTE of the supporting substrate 150. In some embodiments, the first portion 102 of the hybrid substrate core 101 may have a relatively high Young's modulus (e.g., ≥30 GPa) providing a higher resistance to mechanical strain, while the second portion 104 of the hybrid substrate core 101 may have a Young's modulus that is less than the Young's modulus of the first portion 102, which may provide a “cushion” effect to mitigate stresses resulting from the CTE mismatch between the semiconductor package structure 130 and the supporting substrate 150 in the assembled semiconductor package 140.

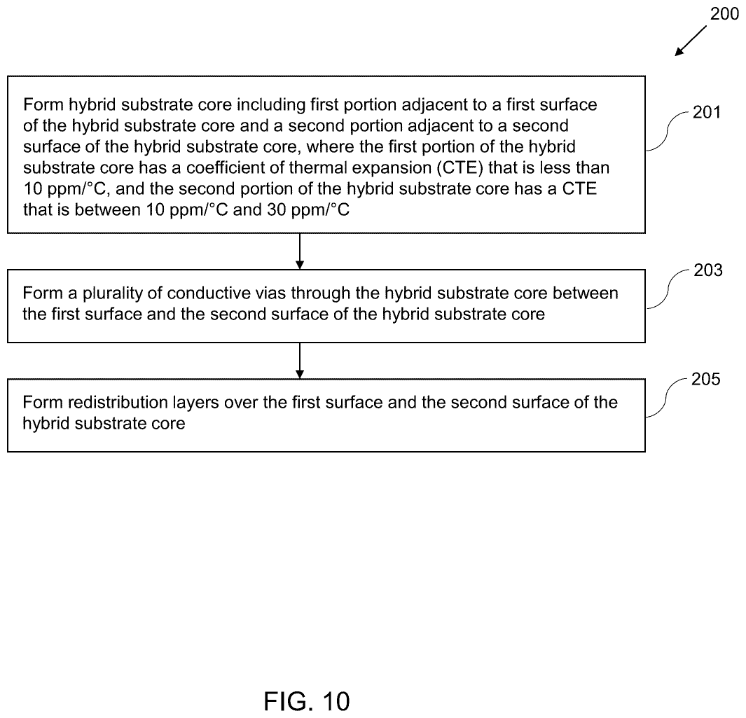

FIG. 10 is a flowchart illustrating a method 200 of fabricating a package substrate 120 according to various embodiments of the present disclosure. Referring to FIGS. 1 and 10, in step 201 of embodiment method 200, a hybrid substrate core 101 including a first portion 102 adjacent to a first surface 105 of the hybrid substrate core 101 and a second portion 104 adjacent to a second surface of the hybrid substrate core 101 may be formed. The first portion 102 of the hybrid substrate core 101 may have a coefficient of thermal expansion (CTE) that is less than 10 ppm/° C., and the second portion 104 of the hybrid substrate core 101 may have a CTE that is between 10 ppm/° C. and 30 ppm/° C.

Referring to FIGS. 2 and 10, in step 203 of embodiment method 200, a plurality of conductive vias 107 may be formed through the hybrid substrate core 101 between the first surface 105 and the second surface 106 of the hybrid substrate core 101. Referring to FIGS. 3, 4 and 10, in step 205 of embodiment method 200, redistribution layers 110 may be formed over the first surface 105 and the second surface 106 of the hybrid substrate core 101.

Referring to all drawings and according to various embodiments of the present disclosure, a substrate 120 for a semiconductor package 140 may include a substrate core 101 having a first surface 105 and a second surface 106 opposite the first surface 105, the substrate core 101 including a first portion 102 adjacent to the first surface 105 and a second portion 104 adjacent to the second surface 106, where the first portion 102 has a coefficient of thermal expansion (CTE) that is less than 10 ppm/° C., and the second portion 104 has a CTE that is between 10 ppm/° C. and 30 ppm/° C., a plurality of conductive vias 107 extending through the substrate core 101 between the first surface 105 and the second surface 106 of the substrate core 101, and a first redistribution layer 110a over the first surface 105 of the substrate core 101, and a second redistribution layer 110b over the second surface 106 of the substrate core 101.

In an embodiment, the first portion 102 of the substrate core 101 has a CTE that is between 0.1 10 ppm/° C. and 10 ppm/° C.

In another embodiment, the first portion 102 of the substrate core 101 has a Young's modulus that is greater than a Young's modulus of the second portion 104 of the substrate core 101.

In another embodiment, the Young's modulus of the first portion 102 of the substrate core 101 is between 30 GPa and 50 GPa, and the Young's modulus of the second portion 104 of the substrate core 101 is between 10 GPa and 40 GPa.

In another embodiment, the first portion 102 of the substrate core 101 includes a first laminate reinforced resin sheet and the second portion 104 of the substrate core 101 includes a second laminate reinforced resin sheet, and the first laminate reinforced resin sheet and the second laminate reinforced resin sheet are bonded together to form the substrate core 101.

In another embodiment, the first laminate reinforced resin sheet and the second laminate reinforced resin sheet each have a thickness that is between 0.2 mm and 0.6 mm.

In another embodiment, the substrate core 101 further includes a third portion 103 located between the first portion 102 and the second portion 104, the third portion 103 having a CTE that is greater than the CTE of the first portion 102 and less than the CTE of the second portion 104, and the third portion 104 has a Young's modulus between 1 GPa and 50 GPa.

In another embodiment, the first portion 102, the second portion 104 and the third portion 103 each include laminate reinforced resin sheets which are bonded together to form the substrate core 101.

In another embodiment, the first redistribution layer 110a and the second redistribution layer 110b each include conductive interconnect structures 109 within an insulating matrix 108, and the package substrate 120 further includes outer coating layers 111 over the respective first redistribution layer 110a and the second redistribution layer 110b.

An additional embodiment is drawn to a semiconductor package 140 including a semiconductor package structure 130 having one or more semiconductor IC dies 131, a package substrate 120 having a first side 114 and a second side 115 opposite the first side 114 and electrical interconnect structures 109 extending between the first side 114 and the second side 115, the package substrate 120 including a hybrid substrate core 101 including a first portion 102 that is closest to the first side 114 of the package substrate 120 and a second portion 104 that is closest to the second side 115 of the package substrate 120, wherein the semiconductor package structure 130 is mounted to the first side 114 of the package substrate 120, and a supporting substrate 150, wherein the second side 115 of the package substrate 120 is mounted to the supporting substrate 150, where the first portion 102 of the hybrid substrate core 101 of the package substrate 120 has a coefficient of thermal expansion (CTE) that is within 5 ppm/° C. of a CTE of a semiconductor IC die 131 of the semiconductor package structure 130, and the second portion 102 of the hybrid substrate core 101 of the package substrate 120 has a CTE that is within 10 ppm/° C. of a CTE of the supporting substrate 150.

In an embodiment, the first portion 102 of the hybrid substrate core 101 of the package substrate 120 has a coefficient of thermal expansion (CTE) that is within 0.1 ppm/° C. of a CTE of a semiconductor IC die 131 of the semiconductor package structure 130, and the second portion 102 of the hybrid substrate core 101 of the package substrate 120 has a CTE that is within 3 ppm/° C. of a CTE of the supporting substrate 150.

In another embodiment, the supporting substrate 150 includes a printed circuit board (PCB) and the second side 115 of the package substrate 120 is mounted to the PCB via a plurality of solder connections 154.

In another embodiment, the second portion 104 of the hybrid substrate core 101 of the package substrate 120 has a Young's modulus that is less than a Young's modulus of the first portion 102 of the hybrid substrate core 101 of the package substrate 120.

In another embodiment, the semiconductor package structure 130 includes a plurality of semiconductor IC dies 131, and the first portion 102 of the hybrid substrate core 101 of the package substrate 120 has a coefficient of thermal expansion (CTE) that is within 5 ppm/° C. of a CTE of each semiconductor IC die 131 of the semiconductor package structure 130.

In another embodiment, the semiconductor package structure 130 further includes an interposer 133, the plurality of semiconductor IC dies 131 mounted to an upper surface of the interposer 133, and the semiconductor package structure 130 is mounted to the first side 114 of the package substrate 120 via a plurality of solder connections 136 extending between a lower surface of the interposer 133 and the first side 114 of the package substrate 120.

In another embodiment, the hybrid substrate core 101 of the package substrate 120 includes a third portion 103 located between the first portion 102 and the second portion 104, where a CTE of the third portion 103 of the hybrid substrate core 101 is greater than a CTE of the first portion 102 of the hybrid substrate core 101 and less than the CTE of the second portion 104 of the hybrid substrate core 101.

An additional embodiment is drawn to a method of fabricating a package substrate that includes forming a hybrid substrate core 101 including a first portion 102 adjacent to a first surface 105 of the hybrid substrate core 101 and a second portion 104 adjacent to a second surface 106 of the hybrid substrate core 101, where the first portion 102 of the hybrid substrate core 101 has a coefficient of thermal expansion (CTE) that is less than 10 ppm/° C., and the second portion 104 of the hybrid substrate core 101 has a CTE that is between 10 ppm/° C. and 30 ppm/° C., forming a plurality of conductive vias 107 through the hybrid substrate core 101 between the first surface 105 and the second surface 106 of the hybrid substrate core 101, forming a first redistribution layers 110a over the first surface 105 of the hybrid substrate core 101, and forming a second redistribution layers 110b over the second surface 106 of the hybrid substrate core 101.

In an embodiment, forming the hybrid substrate core 101 includes forming a plurality of laminate reinforced resin sheets, and bonding the plurality of laminate resin reinforced sheets together to form the hybrid substrate core 101, where a first laminate reinforced resin sheet forms the first portion 102 of the hybrid substrate core 101 and a second laminate reinforced resin sheet forms the second portion 104 of the hybrid substrate core 101.

In another embodiment, a third laminate reinforced resin sheet of the plurality of laminate reinforced resin sheets forms a third portion 103 of the hybrid substrate core 101, where a CTE of the third portion 103 of the hybrid substrate core 101 is greater than a CTE of the first portion 102 of the hybrid substrate core 101 and is less than a CTE of the second portion 104 of the hybrid substrate core 101.

In another embodiment, a Young's modulus of the first portion 102 of the hybrid substrate core 101 is between 30 GPa and 50 GPa, and a Young's modulus of the second portion 104 of the hybrid substrate core 101 is between 10 GPa and 40 GPa, and the Young's modulus of the first portion 102 of the hybrid substrate core 101 is greater than the Young's modulus of the second portion 104 of the hybrid substrate core 101.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A substrate for a semiconductor package, comprising:
a substrate core having a first surface and a second surface opposite the first surface, the substrate core comprising:
a first portion adjacent to the first surface; and
a second portion adjacent to the second surface, wherein the first portion has a coefficient of thermal expansion (CTE) that is less than 10 ppm/° C., and the second portion has a CTE that is between 10 ppm/° C. and 30 ppm/° C.;
a plurality of conductive vias extending through the substrate core between the first surface and the second surface of the substrate core;
a first redistribution layer over the first surface of the substrate core; and
a second redistribution layer over the second surface of the substrate core.

2. The substrate of claim 1, wherein the first portion of the substrate has a CTE that is between 0.1 10 ppm/° C. and 10 ppm/° C.

3. The substrate of claim 1, wherein the first portion of the substrate core has a Young's modulus that is greater than a Young's modulus of the second portion of the substrate core.

4. The substrate of claim 3, wherein the Young's modulus of the first portion of the substrate core is between 30 GPa and 50 GPa, and the Young's modulus of the second portion of the substrate core is between 10 GPa and 40 GPa.

5. The substrate of claim 3, wherein the first portion of the substrate core comprises a first laminate reinforced resin sheet and the second portion of the substrate core comprises a second laminate reinforced resin sheet, and the first laminate reinforced resin sheet and the second laminate reinforced resin sheet are bonded together to form the substrate core.

6. The substrate of claim 5, wherein the first laminate reinforced resin sheet and the second laminate reinforced resin sheet each have a thickness that is between 0.2 mm and 0.6 mm.

7. The substrate of claim 3, wherein the substrate core further comprises a third portion located between the first portion and the second portion, the third portion having a CTE that is greater than the CTE of the first portion and less than the CTE of the second portion, and the third portion has a Young's modulus between 1 GPa and 50 GPa.

8. The substrate of claim 7, wherein the first portion, the second portion and the third portion each comprise laminate reinforced resin sheets which are bonded together to form the substrate core.

9. The substrate of claim 1, wherein the first redistribution layer and the second redistribution layer each comprise conductive interconnect structures within an insulating matrix, and the substrate further comprises outer coating layers over the respective first redistribution layer and the second redistribution layer.

10. A semiconductor package, comprising:
a semiconductor package structure comprising one or more semiconductor IC dies;
a package substrate having a first side and a second side opposite the first side and electrical interconnect structures extending between the first side and the second side, the package substrate comprising a hybrid substrate core comprising:
a first portion that is closest to the first side of the package substrate; and
a second portion that is closest to the second side of the package substrate, wherein the semiconductor package structure is mounted to the first side of the package substrate; and
a supporting substrate, wherein the second side of the package substrate is mounted to the supporting substrate, wherein the first portion of the hybrid substrate core of the package substrate has a coefficient of thermal expansion (CTE) that is within 5 ppm/° C. of a CTE of a semiconductor IC die of the semiconductor package structure, and the second portion of the hybrid substrate core of the package substrate has a CTE that is within 10 ppm/° C. of a CTE of the supporting substrate.

11. The semiconductor package of claim 10, wherein the first portion of the hybrid substrate core of the package substrate has a coefficient of thermal expansion (CTE) that is within 0.1 ppm/° C. of a CTE of a semiconductor IC die of the semiconductor package structure, and the second portion of the hybrid substrate core of the package substrate has a CTE that is within 3 ppm/° C. of a CTE of the supporting substrate.

12. The semiconductor package of claim 10, wherein the supporting substrate comprises a printed circuit board (PCB) and the second side of the package substrate is mounted to the PCB via a plurality of solder connections.

13. The semiconductor package of claim 10, wherein the second portion of the hybrid substrate core of the package substrate has a Young's modulus that is less than a Young's modulus of the first portion of the hybrid substrate core of the package substrate.

14. The semiconductor package of claim 10, wherein the semiconductor package structure comprises a plurality of semiconductor IC dies, and the first portion of the hybrid substrate core of the package substrate has a coefficient of thermal expansion (CTE) that is within 5 ppm/° C. of a CTE of each semiconductor IC die of the semiconductor package structure.

15. The semiconductor package of claim 14, wherein the semiconductor package structure further comprises an interposer, the plurality of semiconductor IC dies mounted to an upper surface of the interposer, and the semiconductor package structure is mounted to the first side of the package substrate via a plurality of solder connections extending between a lower surface of the interposer and the first side of the package substrate.

16. The semiconductor package of claim 10, wherein the hybrid substrate core of the package substrate comprises a third portion located between the first portion and the second portion, wherein a CTE of the third portion of the hybrid substrate core is greater than a CTE of the first portion of the hybrid substrate core and less than the CTE of the second portion of the hybrid substrate core.

17. A method of fabricating a package substrate, comprising:
forming a hybrid substrate core comprising a first portion adjacent to a first surface of the hybrid substrate core and a second portion adjacent to a second surface of the hybrid substrate core, wherein the first portion of the hybrid substrate core has a coefficient of thermal expansion (CTE) that is less than 10 ppm/° C., and the second portion of the hybrid substrate core has a CTE that is between 10 ppm/° C. and 30 ppm/° C.;
forming a plurality of conductive vias through the hybrid substrate core between the first surface and the second surface of the hybrid substrate core;
forming a first redistribution layer over the first surface of the hybrid substrate core; and
forming a second redistribution layer over the second surface of the hybrid substrate core.

18. The method of claim 17, wherein forming the hybrid substrate core comprises forming a plurality of laminate reinforced resin sheets, and bonding the plurality of laminate resin reinforced sheets together to form the hybrid substrate core, wherein a first laminate reinforced resin sheet forms the first portion of the hybrid substrate core and a second laminate reinforced resin sheet forms the second portion of the hybrid substrate core.

19. The method of claim 18, wherein a third laminate reinforced resin sheet of the plurality of laminate reinforced resin sheets forms a third portion of the hybrid substrate core, wherein a CTE of the third portion of the hybrid substrate core is greater than a CTE of the first portion of the hybrid substrate core and is less than a CTE of the second portion of the hybrid substrate core.

20. The method of claim 17, wherein a Young's modulus of the first portion of the hybrid substrate core is between 30 GPa and 50 GPa, and a Young's modulus of the second portion of the hybrid substrate core is between 10 GPa and 40 GPa, and the Young's modulus of the first portion of the hybrid substrate core is greater than the Young's modulus of the second portion of the hybrid substrate core.
